(19) United States
(12) Patent Application Publication
(10) Pub. No.: US 2003/0071647 A1
(43) Pub. Date: Apr. 17, 2003

(54) Method and arrangement for determining the high-frequency behavior of active circuit elements

(76) Inventors: Martin Schaefer, Ahrensburg (DE); Andreas Wichern, Hamburg (DE)

Correspondence Address: U.S. Philips Corporation, 580 White Plains Road, Tarrytown, NY, 10591, US

(21) Appl. No.: 10/227,232

(22) Filed: Aug. 23, 2002

(30) Foreign Application Priority Data
Aug. 28, 2001 (DE) 10142021.8

(51) Int. Cl. G01R 31/26

(52) U.S. Cl. 324/765

(57) ABSTRACT

In a method and an arrangement for determining the high-frequency behavior of active circuit elements in circuits arranged on a wafer, in which, substitutionally for the active circuit elements in the circuits, active circuit elements are utilized in process control modules which are also arranged on the wafer, the oscillation frequency of ring oscillators comprised in the process control modules and constituted by active circuit elements is measured and evaluated.

The invention relates to a method of determining the high-frequency behavior of active circuit elements in circuits arranged on a wafer, in which, substitutionally for the active circuit elements in the circuit, active circuit elements are utilized in process control modules which are also arranged on the wafer.

To be able to recognize properties of the single components of integrated circuits as early as possible in the production process, not only the circuits to be produced but also process control modules are arranged on the wafers, which thus have been subjected to the same processes as the circuits and are designed for relatively simple measurements. The process control modules comprise essentially the same single components that constitute the circuits. The measurements can be performed at the end of the process of manufacturing the circuit so as to check the wafer manufacturing process and, if necessary, optimize them for subsequent charges. Such a method is known from, for example, U.S. Pat. No. 4,079,505. Another method using process control modules is described in U.S. Pat. No. 4,364,010, which, likewise as the first mentioned method, is based on a DC characterization of bipolar transistors.

In accordance with the requirements imposed by the progressing communication technique, semiconductor circuits are required for very high frequencies, at which the transit frequency for bipolar transistors is in the range of, for example, 10 GHz to 50 GHz. The transit frequency is a value which is often used for describing high-frequency properties and is the frequency at which the bipolar transistor has only a gain of 1. The actual operating frequency of bipolar transistors is maximally at ⅓ of the transit frequency. Also MOS transistors can only be used within given frequencies. At higher frequencies, they lose the properties required for the circuit.

It is an object of the present invention to provide a method and an arrangement with which the high-frequency behavior of active circuit elements on the wafer can be directly determined at the end of the manufacturing process.

In the method according to the invention, this object is achieved in that the oscillation frequency of ring oscillators comprised in the process control modules and constituted by transistors is measured and evaluated.

By using a ring oscillator, the frequency which must be detected while using corresponding measuring equipment and contact devices (connections, contact pins) is relatively low. It is, for example, about 600 MHz when using a ring oscillator with 10 stages, when the transistors have a transit frequency of about 10 GHz.

The method according to the invention is essentially suitable to be performed at the end of the process of manufacturing the active circuit elements on the wafer. Rejections can then be timely recognized before performing further cost-intensive manufacturing steps such as, for example, slicing the circuits and making them ready for use. Moreover, data for adjusting the parameters can be gained for subsequent charges. The invention is applicable for different active circuit elements such as bipolar transistors, field effect transistors and other amplifying elements which can be manufactured on wafers.

The measured oscillation frequency may be based on a go/no go assessment when corresponding comparison values are known. In many cases, one is interested in determining the transit frequencies of the transistors. A further embodiment of the method according to the invention is therefore characterized in that, for gaining values for the transit frequency of the transistors, the oscillation frequency is measured on at least one wafer and the transit frequency of said transistors is measured by means of a measuring method outside the manufacturing process, in that the measured values are composed to a calibration table, and in that, in the continuous measurements of the oscillation frequencies, the transit frequencies are determined from the oscillation frequencies during the manufacturing process and with reference to the calibration table.

In a further embodiment of the method, further facts can be gained about the quality of the transistors in that the oscillation frequencies are measured at a plurality of collector currents.

If, in spite of using the ring oscillator, the frequency to be measured were still too high for the practical requirements, it may be ensured by means of another embodiment that the oscillation frequency is divided within the relevant process control module and that a signal having the divided frequency is taken from the relevant process control module and applied to a frequency meter.

An arrangement according to the invention is characterized in that the process control modules comprise ring oscillators constituted by transistors, whose output signals can be derived from the process control modules and are applicable to an evaluation device. The evaluation device essentially comprises a frequency meter, a microcomputer and associated memories for processing measuring programs and storing measuring data.

The arrangement according to the invention may be further characterized in that, for gaining values for the transit frequency of the transistors, the evaluation device is formed in such a way that it measures the frequency of the output signals (oscillation frequency) and determines the transit frequencies from the oscillation frequencies with reference to a calibration table, said calibration table being drawn up by measuring the oscillation frequency on at least one wafer and measuring the transit frequency of transistors in the same process control modules by means of a measuring method outside the manufacturing process.

Another embodiment of the arrangement according to the invention is characterized in that the process control modules comprise frequency dividers which are connected to the ring oscillators, and in that a signal having the divided frequency can be applied by the relevant frequency divider to the evaluation device.

A very favorable realization of the ring oscillator in an advantageous embodiment is characterized in that the ring oscillator is built up in the ECL technique.

These and other aspects of the invention are apparent from and will be elucidated with reference to the embodiments described hereinafter.

In the drawings:

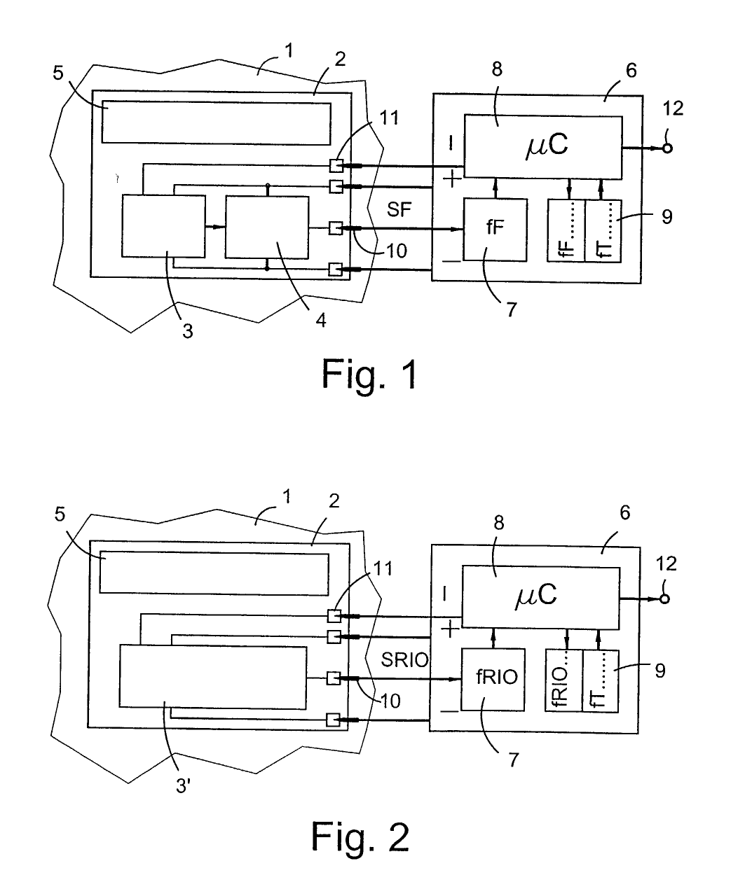

FIG. 1 shows diagrammatically a first embodiment,

FIG. 2 shows diagrammatically a second embodiment,

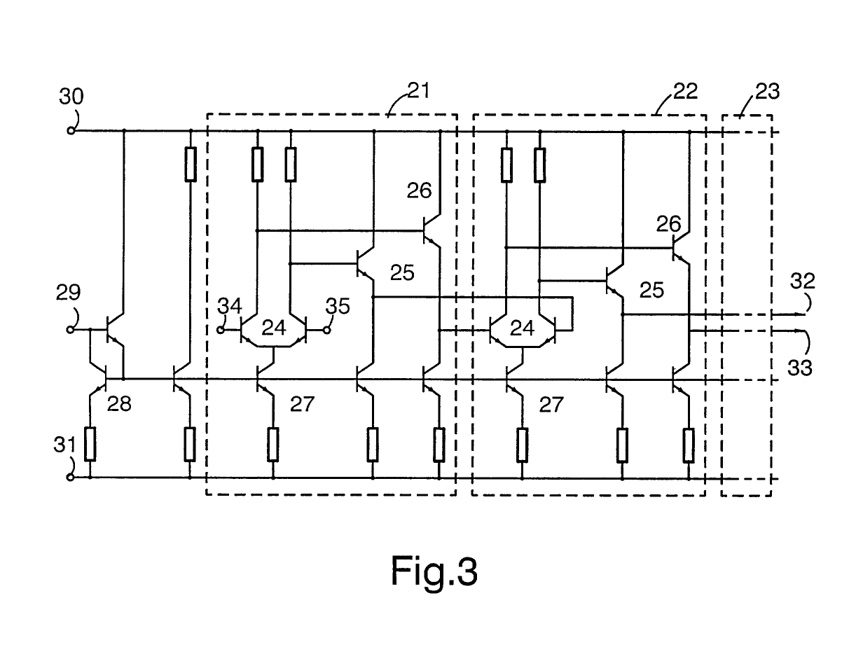

FIG. 3 shows a circuit diagram of a ring oscillator, and

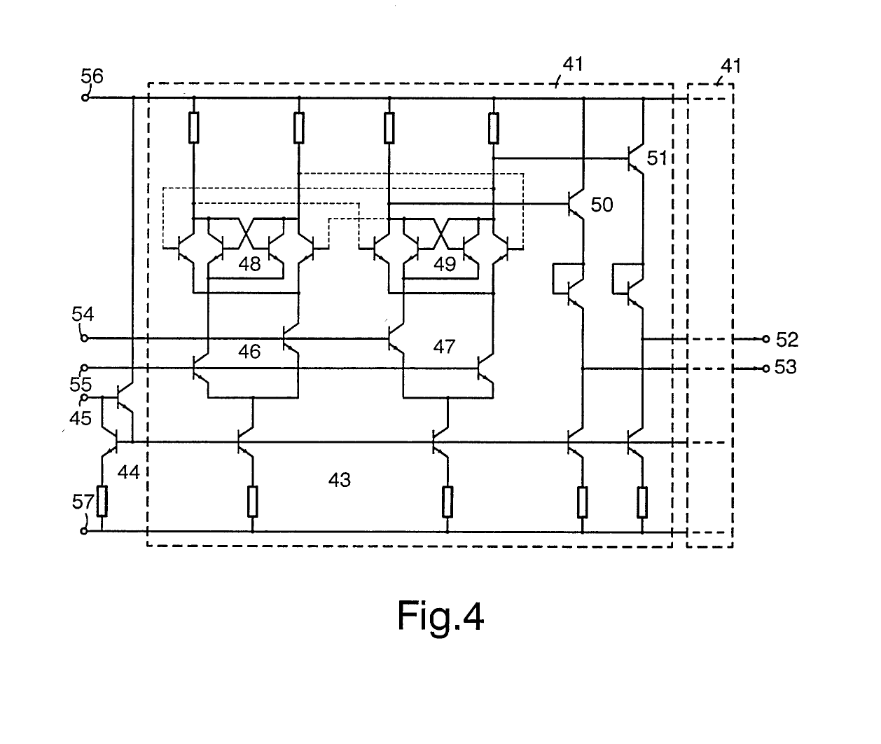

FIG. 4 shows a circuit diagram of a frequency divider.

FIG. 1 shows diagrammatically a wafer 1 with a process control module 2. It comprises a ring oscillator 3, a frequency divider 4 and further test circuits 5 which do not need any further explanation with reference to the present invention and are therefore not shown individually. A test device 6 essentially comprises a frequency meter 7, a microcomputer 8 and a memory 9. Further circuits, for example, power supply circuits are not shown for the sake of clarity.

The test device 6 further comprises measuring cables whose tip-shaped contacts 10 are put on contact faces 11 for measuring the process control module. The ring oscillator 3 and the frequency divider 4 receive an operating voltage which is symbolized by the signs + and −. Furthermore, the ring oscillator 3 has a value I for controlling the collector current. An input 7 of the frequency meter receives the output signal SF with the frequency fF. The frequency meter 7 passes on the relevant measuring value to the microcomputer 8. This value is stored whereupon the next current value is adjusted via the value I. After the frequencies fF have been measured for all current values concerned, the maximum is fixed in the microcomputer 8 and the associated transit frequency fT is derived from the table stored in the memory 9 and is applied to an output 12.

In the embodiment shown in FIG. 2, a ring oscillator 3′ with more stages for achieving a frequency which is suitable for the practical measurement is used instead of the frequency divider. The output signal SRIO of the ring oscillator is thus measured with the frequency fRIO and used for reading from the table.

FIG. 3 shows a ring oscillator by way of example, as can be implemented in an integrated circuit technique. Except for the number of stages of the ring oscillator, almost only the signal delay time of the transistors influences the oscillation frequency. Therefore, there is a good correlation between the oscillation frequency and the transit frequency that is of interest. The circuit shown in FIG. 3 only represents one of many possible circuit variants which are known to those skilled in the art, for building up ring oscillators.

Only two stages 21, 22 of the ten stages which are required, for example, for the ring oscillator are shown extensively, whereas further stages are only indicated at 23. Each stage consists of a differential amplifier 24 and emitter followers 25, 26. Both the differential amplifiers 24 and the emitter followers 25, 26 are controlled via constant current sources 27. To adjust the current and hence the collector current of the differential amplifier 24, a current mirror circuit 28 is used which receives the current I predetermined by the test device at 29 via the corresponding contact face (FIGS. 1 and 2). Further connections 30, 31 are used for applying the operating voltage.

The outputs 32, 33 of the last stage (at 23) are connected to the inputs 34, 35 of the first stage 21. The output signal of the ring oscillator can be derived from one or both of these outputs and can be applied to the test device either directly (FIG. 2) or via a frequency divider (FIG. 1).

FIG. 4 shows an embodiment of a frequency divider in which only one divider stage 41 is shown in greater detail, whereas further divider stages 42 are only indicated. Also in this circuit, constant current sources 43 are provided, in which the test device supplies the current via a current mirror circuit 44 and via a corresponding contact face at 45. Each divider stage consists of two parallel controlled differential amplifiers 46, 47 whose collector circuits comprise flip-flops 48, 49, whose outputs are connected via emitter followers 50, 51 to the next stage or, in the case of the last divider stage, to outputs 52, 53. The output signal of the ring oscillator is applied to inputs 54, 55, while the output signal SF of the frequency divider can be taken from the outputs 52, 53. The operating voltage is applied to the circuit points 56, 57.

1. A method of determining the high-frequency behavior of active circuit elements in circuits arranged on a wafer, in which, substitutionally for the active circuit elements in the circuit, active circuit elements are utilized in process control modules which are also arranged on the wafer, characterized in that the oscillation frequency of ring oscillators comprised in the process control modules and constituted by active circuit elements is measured and evaluated.

2. A method as claimed in claim 1, characterized in that, for gaining values for the transit frequency of the transistors, the oscillation frequency is measured on at least one wafer and the transit frequency of said transistors is measured by means of a measuring method outside the manufacturing process, in that the measured values are composed to a calibration table, and in that, in the continuous measurements of the oscillation frequencies, the transit frequencies are determined from the oscillation frequencies during the manufacturing process and with reference to the calibration table.

3. A method as claimed in any one of the preceding claims, characterized in that the oscillation frequencies are measured at a plurality of collector currents.

4. A method as claimed in any one of the preceding claims, characterized in that the oscillation frequency is divided within the relevant process control module and in that a signal having the divided frequency is taken from the relevant process control module and applied to a frequency meter.

5. An arrangement for determining the high-frequency behavior of transistors in circuits arranged on a wafer (1), in which, substitutionally for the transistors in the circuits, transistors are utilized in process control modules (2) which are also arranged on the wafer (1), characterized in that the process control modules (2) comprise ring oscillators (3, 3′) constituted by transistors, whose output signals can be derived from the process control modules (2) and are applicable to an evaluation device (6).

6. An arrangement as claimed in claim 5, characterized in that, for gaining values for the transit frequency of the transistors, the evaluation device (6) is formed in such a way that it measures the frequency of the output signals (oscillation frequency) and determines the transit frequencies from the oscillation frequencies with reference to a calibration table (9), said calibration table (9) being drawn up by measuring the oscillation frequency on at least one wafer (1) and by measuring the transit frequency of transistors in the same process control modules (2) by means of a measuring method outside the manufacturing process.

7. An arrangement as claimed in claims 5 and 6, characterized in that the process control modules (2) comprise frequency dividers (4) which are connected to the ring oscillators (3), and in that a signal having the divided frequency can be applied by the relevant frequency divider (4) to the evaluation device (6).

8. An arrangement as claimed in any one of claims 5 to 7, characterized in that the ring oscillator (3, 3′) is built up in the ECL technique.
